(19) United States
(12) Patent Application Publication
(10) Pub. No.: US 2026/0276745 A1
(43) Pub. Date: Sep. 17, 2026

(54) MAGNETIC SENSOR

(71) Applicant: TDK Corporation, Tokyo (JP)

(72) Inventor: Kenzo MAKINO, Tokyo (JP)

(21) Appl. No.: 19/537,699

(22) Filed: Feb. 12, 2026

(30) Foreign Application Priority Data
Mar. 14, 2025 (JP) 2025-041374

(51) Int. Cl. G01R 33/00; G01R 33/09

(52) U.S. Cl. CPC G01R 33/0011; G01R 33/093

(57) ABSTRACT

A magnetic sensor comprises a magnetic body and a first magnetic field sensing element that has a magnetic field sensing direction in a first direction. In the first direction, the center of the magnetic body is at a position different from the center of the first magnetic field sensing element. The magnetic body is located apart from the first magnetic field sensing element in a second direction which is the direction of thickness of the first magnetic field sensing element. The magnetic body includes a soft magnetic layer and a first fixed magnetization portion whose magnetization direction is fixed with respect to an external magnetic field. In a plan view from a third direction that is orthogonal to each of the first and second directions, the first fixed magnetization portion is closer to the first magnetic field sensing element than is the center of the magnetic body.

### FIELD

This application claims the benefit of Japanese Priority Patent Application No. JP 2025-041374 filed on Mar. 14, 2025, the entire contents of which are incorporated herein by reference.

The present disclosure relates to a magnetic sensor.

### BACKGROUND

JP 2018-163115 A describes a magnetic sensor that comprises a magnetic body made of a soft magnetic material in the vicinity of a magnetic field sensing element. The magnetic body increases the magnetic field strength that is applied to the magnetic field sensing element and thus increases the magnetic field sensing sensitivity of the magnetic field sensing element.

### SUMMARY

The magnetic sensor of the present disclosure comprises a magnetic body and a first magnetic field sensing element that has a magnetic field sensing direction in a first direction. The center of the magnetic body in the first direction is at a position different from the center of the first magnetic field sensing element. The magnetic body is located apart from the first magnetic field sensing element in a second direction which is the direction of thickness of the first magnetic field sensing element. The magnetic body includes a soft magnetic layer and a first fixed magnetization portion whose magnetization direction is fixed with respect to an external magnetic field. In one aspect, the first fixed magnetization portion is closer to the first magnetic field sensing element than is the center of the magnetic body in a plan view from a third direction that is orthogonal to each of the first and second directions. In another aspect, the magnetic body includes an edge that faces the first magnetic field sensing element along the third direction that is orthogonal to each of the first and second directions, and the first fixed magnetization portion is provided along the edge.

### BRIEF DESCRIPTION OF THE DRAWINGS

The accompanying drawings are included to provide a further understanding of the disclosure and are incorporated in and constitute a part of this specification. The drawings illustrate example embodiments and together with the specification explain the principles of the technology.

FIG. 1A is a plan view of a magnetic sensor of a first embodiment;

FIG. 1B is a cross-sectional view of the magnetic sensor of the first embodiment;

FIG. 2A is an enlarged plan view of a portion of FIG. 1A;

FIG. 2B is an enlarged cross-sectional view of a portion of FIG. 1B;

FIG. 3 is a cross-sectional view of a magnetic field sensing element;

FIG. 4A is a schematic diagram showing the magnetization of a magnetic body in a comparative example;

FIG. 4B is a schematic diagram showing the magnetization of a magnetic body in the first embodiment;

FIGS. 5A-5C are plan views of modifications of the magnetic body;

FIGS. 6A-6C are enlarged cross-sectional views of portions of a magnetic sensor according to modifications of the first embodiment;

FIG. 7A is a plan view of a magnetic sensor according to a second embodiment;

FIG. 7B is a cross-sectional view of the magnetic sensor according to the second embodiment;

FIG. 8 is an enlarged cross-sectional view of a portion of FIG. 7B;

FIG. 9 is an enlarged cross-sectional view of a portion of the magnetic sensor according to a modification of the second embodiment; and

FIG. 10 is an enlarged partial cross-sectional view of a portion of the magnetic sensor according to another modification of the second embodiment.

### DETAILED DESCRIPTION

In the following explanation, some example embodiments and modifications of the technology are described in detail with reference to the accompanying drawings. Note that the following description is directed to illustrative examples of the disclosure and are not to be construed as limiting the technology. Factors including, without limitation, numerical values, shapes, materials, components, positions of the components, and the manner in which components are coupled to each other are illustrative only and are not to be construed as limiting the technology. Further, elements in the following example embodiments that are not recited in a most-generic independent claim of the disclosure are optional and may be provided on an as-needed basis. The drawings are schematic and are not intended to be drawn to scale. Like elements are denoted with the same reference numerals to avoid redundant descriptions.

When an external magnetic field is applied to a magnetic body made of soft magnetic material, the magnetic body is magnetized in the direction of the external magnetic field, but this magnetization state almost disappears when the application of the external magnetic field stops. However, when a large magnetic field is applied, magnetic domains in which the direction of magnetization faces outward of the magnetic body may form near the surface of the magnetic body after the application of the magnetic field stops. Such magnetic domains may produce a leakage magnetic field that can lead to an offset in the output of the magnetic sensor. An object of the present disclosure is to provide a magnetic sensor that suppresses leakage magnetic fields generated from a magnetic body after application of an external magnetic field.

Embodiments of the present disclosure will be described below. In the following description and drawings, the magnetic field sensing direction of magnetic field sensing element 2 is referred to as the first direction or X-direction, and the direction of thickness of magnetic field sensing element 2 is referred to as the second direction or Z-direction. The direction of thickness of magnetic field sensing element 2 corresponds to the direction in which free magnetization layer 21, non-magnetic layer 22, and fixed magnetization layer 23 of magnetic field sensing element 2 are stacked. The direction that is orthogonal to each of the first direction (X-direction) and the second direction (Z-direction) is referred to as the third direction or Y-direction. The two directions directed in opposite directions to each other in the Y-direction may be referred to as the +Y-direction and the −Y-direction, and the two directions directed in opposite directions to each other in the Z-direction may be referred to as the +Z-direction and the −Z-direction.

### First Embodiment

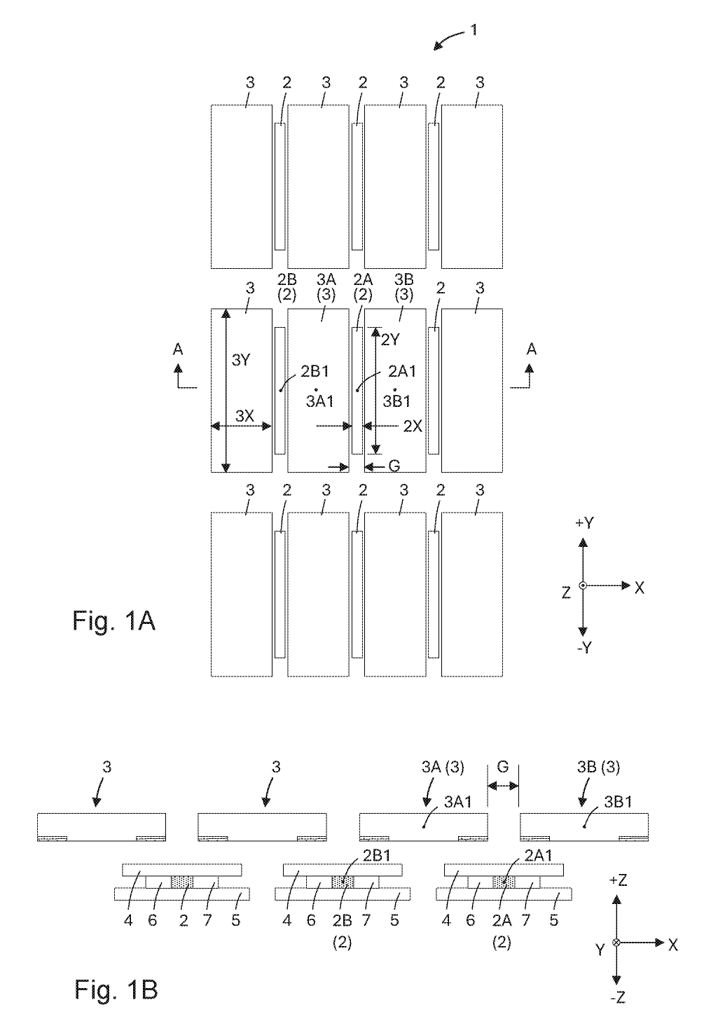

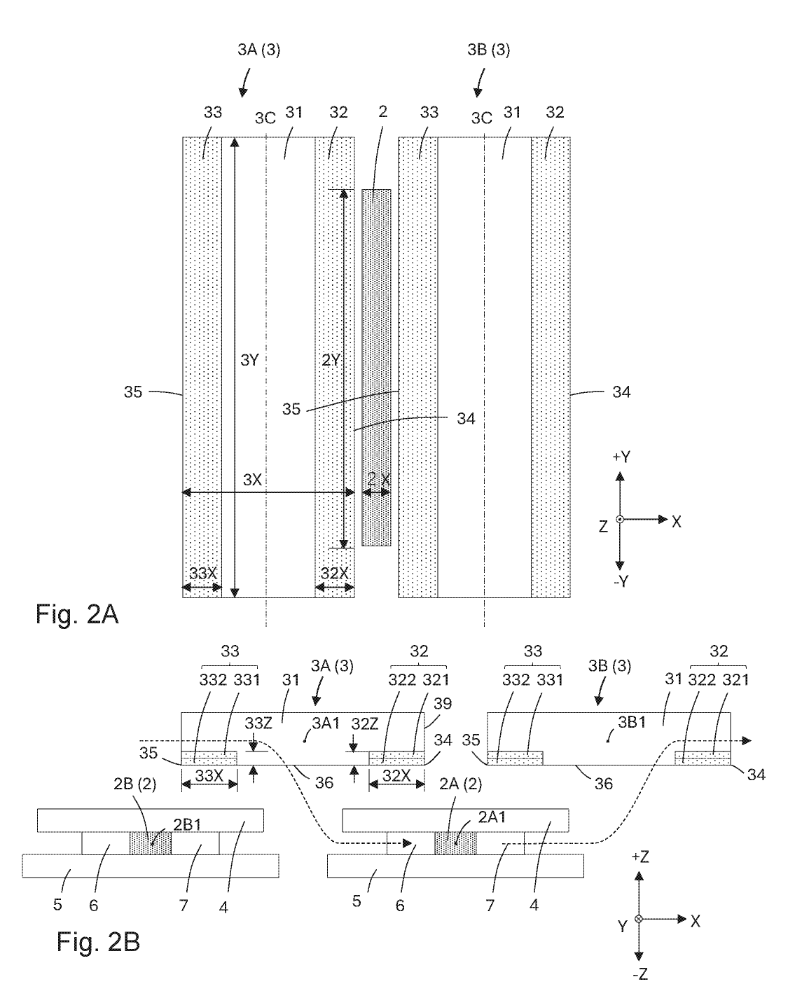

FIG. 1A is a plan view of magnetic sensor 1 according to the first embodiment. FIG. 1B is a cross-sectional view along line A−A in FIG. 1A showing magnetic sensor 1 according to the first embodiment. FIG. 2A is an enlarged plan view of a portion of FIG. 1A. FIG. 2B is an enlarged cross-sectional view of a portion of FIG. 1B. In FIG. 2A, first fixed magnetization portion 32 and second fixed magnetization portion 33 are shown for the sake of convenience. In FIGS. 1A and 2A, the depiction of first electrode 4, second electrode 5, first soft magnetic layer 6, and second soft magnetic layer 7 is omitted. Magnetic sensor 1 comprises a plurality of magnetic field sensing elements 2 having a magnetic field sensing direction in the X-direction and a plurality of magnetic bodies 3. As shown in FIG. 1A, the plurality of magnetic field sensing elements 2 is arranged spaced apart from one another in the X-direction and Y-direction and arranged to form a plurality of rows in the X-direction and to form a plurality of columns in the Y-direction. The plurality of magnetic bodies 3 is also arranged spaced apart from one another in the X-direction and Y-direction and is arranged to form a plurality of rows in the X-direction and to form a plurality of columns in the Y-direction. For example, each magnetic field sensing element 2 is arranged between magnetic bodies 3 adjacent to each other in the X-direction. Two magnetic field sensing elements 2 adjacent to each other in the X-direction are referred to as first magnetic field sensing element 2A and second magnetic field sensing element 2B. Two magnetic bodies 3 adjacent to each other in the X-direction are referred to as first magnetic body 3A and second magnetic body 3B (the other magnetic body). The plurality of magnetic field sensing elements 2 may each have the same configuration and shape, and the plurality of magnetic bodies 3 may also each have the same configuration and shape.

Center 2A1 of first magnetic field sensing element 2A in the X-direction (or as viewed from the Z-direction) is located between center 3A1 of first magnetic body 3A and center 3B1 of second magnetic body 3B. In the present embodiment, center 2A1 of first magnetic field sensing element 2A in the X-direction is located within gap G between first magnetic body 3A and second magnetic body 3B. First magnetic field sensing element 2A is located within gap G between first magnetic body 3A and second magnetic body 3B in the X-direction but may overlap at least one of first magnetic body 3A and second magnetic body 3B in the X-direction (or as viewed from the Z-direction). In the X-direction, center 3A1 of first magnetic body 3A is located at a different position from center 2A1 of first magnetic field sensing element 2A and from center 2B1 of second magnetic field sensing element 2B. Specifically, in the X-direction, center 3A1 of first magnetic body 3A is located between center 2A1 of first magnetic field sensing element 2A and center 2B1 of second magnetic field sensing body 2B. Center 2A1 (or 2B1) is the center of gravity of first magnetic field sensing element 2A (or of second magnetic field sensing element 2B) but it can also be considered as the center of the figure of first magnetic field sensing element 2A (or of second magnetic field sensing element 2B) in the XZ cross section shown in FIGS. 1B and 2B. Similarly, center 3A1 (or 3B1) is the center of gravity of first magnetic body 3A (or of second magnetic body 3B) but can also be considered as the center of the figure of first magnetic body 3A (or second magnetic body 3B) in the XZ cross section shown in FIGS. 1B and 2B.

Each of the plurality of magnetic field sensing elements 2 is roughly rectangular when viewed from the Z-direction, and length 2Y in the Y-direction is longer than length 2X in the X-direction. Due to the resulting shape anisotropy, the magnetization direction of free magnetization layer 21 (to be described below) of magnetic field sensing element 2 is directed in the Y-direction when no external magnetic field is applied.

As shown in FIG. 1B, the plurality of magnetic bodies 3 is located spaced apart from the plurality of magnetic field sensing elements 2 in the Z-direction. The plurality of magnetic field sensing elements 2 is provided on the same side of magnetic bodies 3 in the Z-direction. In the present embodiment, the plurality of magnetic field sensing elements 2 is provided at the same position in the Z-direction and the plurality of magnetic bodies 3 is provided at the same position in the Z-direction.

Magnetic sensor 1 comprises a plurality of first electrodes 4 and a plurality of second electrodes 5. Each of first electrodes 4 and each of second electrodes 5 correspond to a respective magnetic field sensing element 2 and supply a sense current to that magnetic field sensing element 2. Each of first electrodes 4 and each of second electrodes 5 correspond to a respective magnetic field sensing element 2 in the Z-direction and each is provided on a respective side of the two sides in the Z-direction of the corresponding magnetic field sensing element 2. First electrodes 4 and second electrodes 5 can be made of a conductive material such as NiFe. Magnetic sensor 1 comprises a plurality of first soft magnetic layers 6 and a plurality of second soft magnetic layers 7. Each first soft magnetic layer 6 and each second soft magnetic layer 7 correspond to a respective magnetic field sensing element 2 and each is provided on a respective side of magnetic field sensing element 2 in the X-direction. First soft magnetic layers 6 and second soft magnetic layers 7 can be made of a soft magnetic material such as NiFe. Non-conductors (not shown) are provided between each magnetic field sensing element 2 and first soft magnetic layer 6 and between each magnetic field sensing element 2 and second soft magnetic layer 7.

First magnetic body 3A and second magnetic body 3B together with first soft magnetic layer 6 and second soft magnetic layer 7 function as a yoke that collects the magnetic flux applied to magnetic field sensing element 2 and increases the magnetic field strength. For example, in FIG. 2B, a portion of the magnetic flux (shown as a dashed line in the figure) travels in the positive direction in the X-direction from the left side of first magnetic body 3A in the figure and is absorbed by first magnetic body 3A. A portion of this magnetic flux passes through first soft magnetic layer 6, magnetic field sensing element 2, and second soft magnetic layer 7, and is then absorbed by second magnetic body 3B and emitted from the right side of second magnetic body 3B. First soft magnetic layer 6 and second soft magnetic layer 7 are not essential and one or both of them may be omitted.

### Configuration of Magnetic Field Sensing Element 2

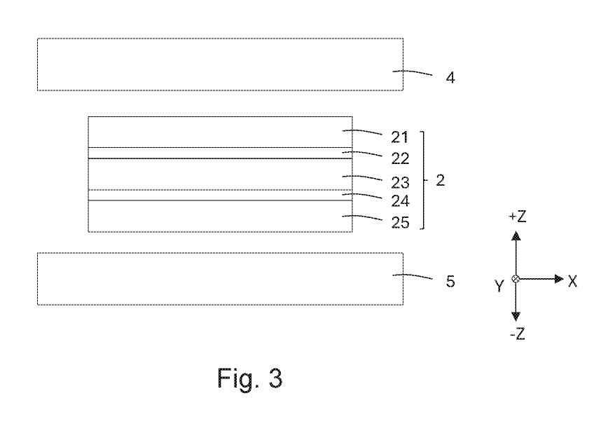

FIG. 3 shows a schematic cross-sectional view of magnetic field sensing element 2. Magnetic field sensing element 2 comprises free magnetization layer 21, nonmagnetic layer 22, first fixed magnetization layer 23, intermediate layer 24, and second fixed magnetization layer 25. These layers 21 to 25 are arranged in the −Z-direction from first electrode 4 to second electrode 5 in the order of free magnetization layer 21, nonmagnetic layer 22, first fixed magnetization layer 23, intermediate layer 24, and second fixed magnetization layer 25. Magnetic field sensing element 2 is electrically connected to first electrode 4 and second electrode 5. A conductive layer such as an underlayer (not shown) may be provided between magnetic field sensing element 2 and first electrode 4, and a conductive layer such as a cap layer (not shown) may be provided between magnetic field sensing element 2 and second electrode 5. Intermediate layer 24 and second fixed magnetization layer 25 may be omitted.

Free magnetization layer 21 is a magnetic layer whose magnetization direction changes in response to an external magnetic field. Free magnetization layer 21 can be made of, for example, CoFe, CoFeB, or NiFe. Nonmagnetic layer 22 is made of an insulating layer such as MgO, or Al₂O₃. Magnetic field sensing element 2 in the present embodiment operates as a tunnel magnetoresistance element (TMR element). Nonmagnetic layer 22 can be made of a nonmagnetic metal layer such as copper or silver, in which case magnetic field sensing element 2 operates as a giant magnetoresistance effect element (GMR element). TMR elements tend to provide higher output than GMR elements. First fixed magnetization layer 23 and second fixed magnetization layer 25 are magnetic layers whose magnetization direction is fixed in the X-direction relative to an external magnetic field. First fixed magnetization layer 23 and second fixed magnetization layer 25 can be made of a laminated film such as Co film or Pt film. Intermediate layer 24 can be made of a nonmagnetic metal such as ruthenium. First fixed magnetization layer 23 is magnetically coupled to second fixed magnetization layer 25 by synthetic antiferromagnetic coupling through intermediate layer 24. The magnetization direction of first fixed magnetization layer 23 is fixed in a direction opposite to that of second fixed magnetization layer 25.

The magnetization direction of free magnetization layer 21 changes with the application of an external magnetic field. That is, when an external magnetic field with a component in the X-direction is applied to free magnetization layer 21, the magnetization direction of free magnetization layer 21 rotates in the XY plane from the Y-direction to the X-direction. This rotation changes the angle between the magnetization direction of free magnetization layer 21 and the magnetization direction of first fixed magnetization layer 23, and the electrical resistance of magnetic field sensing element 2 changes due to the magnetoresistance effect. By detecting the change in electrical resistance of magnetic field sensing element 2, the intensity of the X-direction component of the external magnetic field can be measured. In this way, magnetic sensor 1 of the present embodiment detects magnetic fields in the X-direction.

Although not shown, a magnetic sensor for detecting a magnetic field in the Y-direction may also be configured in the same manner as in the present embodiment. Specifically, a magnetic sensor that detects a magnetic field in the Y-direction can be obtained by rotating the entirety of magnetic sensor 1 shown in FIG. 1B by 90 degrees. Although the present embodiment describes magnetic sensor 1 that detects a magnetic field in the X-direction, the following description may be applied to a magnetic sensor that detects a magnetic field in the Y-direction.

### Configuration of First Magnetic Body 3A

The configuration of first magnetic body 3A will next be described. The configuration of second magnetic body 3B and other magnetic bodies 3 may be the same as that of first magnetic body 3A. First magnetic body 3A comprises soft magnetic layer 31, and further, first fixed magnetization portion 32 and second fixed magnetization portion 33 whose magnetization directions are fixed with respect to an external magnetic field. Furthermore, first fixed magnetization portion 32 comprises first fixed magnetization film 321 that contacts soft magnetic layer 31 and base film 322 that improves the holding power of first fixed magnetization film 321. Second fixed magnetization portion 33 is located apart from first fixed magnetization portion 32 in the X-direction. First fixed magnetization portion 32 and second fixed magnetization portion 33 have the same shape and are arranged symmetrically with respect to center line 3C parallel to the longitudinal direction (Y-direction) of magnetic body 3 but they may have different shapes from each other or may be arranged asymmetrically. The magnetization directions of first fixed magnetization portion 32 and second fixed magnetization portion 33 are oriented in the same direction, e.g., the +Y-direction in the present embodiment, but they may also be oriented in the −Y-direction. Soft magnetic layer 31 can be made using a soft magnetic material such as NiFe.

The materials making up each of first fixed magnetization film 321 and base film 322 depend on the configuration of first fixed magnetization portion 32. As an example, first fixed magnetization film 321 can be made using a ferromagnetic material that is an alloy or laminate film containing at least one of, for example, Co, Fe, Ni, and B. First fixed magnetization portion 32 may include an antiferromagnetic film (not shown) between first fixed magnetization film 321 and base film 322. The antiferromagnetic film can be made using, for example, an alloy containing at least one of, for example, Ir, Mn, and Pt. Base film 322 can be made using an alloy or laminate film containing at least one of, for example, Ta, Ru, Cu, N, and Pt. Base film 322 may be formed on the side of the antiferromagnetic film that is opposite the side that is in contact with first fixed magnetization film 321 such that base film 322 contacts the antiferromagnetic film. In other words, in this example, soft magnetic layer 31 and first fixed magnetization portion 32 may be stacked in the order of base film 322, the antiferromagnetic film, first fixed magnetization film 321, and soft magnetic layer 31.

As another example, first fixed magnetization film 321 can be made using a ferromagnetic material that is an alloy or laminate film containing at least one of, for example, Co, Fe, Ni, and B. First fixed magnetization portion 32 may include a nonmagnetic film (not shown), a second ferromagnetic film (not shown), and an antiferromagnetic film (not shown) made of antiferromagnetic material between first fixed magnetization film 321 and base film 322. The nonmagnetic film can be made using an alloy containing at least one of, for example, Ru, and Ir. The nonmagnetic film may be formed on the side of first fixed magnetization film 321 that is opposite the side that is in contact with soft magnetic layer 31.

The ferromagnetic film (not shown) can be made using the same ferromagnetic material as first fixed magnetization film 321. The ferromagnetic film may be formed so as to contact the nonmagnetic film on the side of the nonmagnetic film that is opposite the side that is in contact with first fixed magnetization film 321. The antiferromagnetic film can be made using an alloy containing at least one of, for example, Ir, Mn, and Pt. The antiferromagnetic film may be formed to contact the ferromagnetic film on the side of the ferromagnetic film that is opposite the side that is in contact with the nonmagnetic film. Base film 322 can be made using an alloy or laminate film containing at least one of, for example, Ta, Ru, Cu, N, and Pt. Base film 322 may be formed to contact the antiferromagnetic film on the side of the antiferromagnetic film that is opposite the side that is in contact with the ferromagnetic film. In other words, in this example, soft magnetic layer 31 and first fixed magnetization portion 32 may be stacked in the order of base film 322, the antiferromagnetic film, the ferromagnetic film, the nonmagnetic film, first fixed magnetization film 321, and soft magnetic layer 31.

As another example, first fixed magnetization film 321 can be made using an alloy (e.g., CoPt, CoCrPt, or FePt) or a laminate film of hard magnetic material containing at least one of, for example, Co, Pt, Cr, and Fe. In this case, base film 322 can be made using an alloy or a laminate film containing at least one of, for example, Cr, Ti, Ta, Ru, Cu, N, and Pt. Base film 322 may be formed on the side of first fixed magnetization film 321 that is opposite the side that is in contact with soft magnetic layer 31. Base film 322 may be formed to contact first fixed magnetization film 321 on the side of first fixed magnetization film 321 that is opposite the side that is in contact with soft magnetic layer 31. In other words, in this example, soft magnetic layer 31 and first fixed magnetization portion 32 may be stacked in the order of base film 322, first fixed magnetization film 321, and soft magnetic layer 31.

First magnetic body 3A includes first edge 34 that faces first magnetic field sensing element 2A and that extends along the Y-direction as viewed from the Z-direction, second edge 35 that faces second magnetic field sensing element 2B and that extends along the Y-direction as viewed from the Z-direction, and element-facing surface 36 that is disposed between first edge 34 and second edge 35 and that faces at least one of first magnetic field sensing element 2A and second magnetic field sensing element 2B in the Z-direction. First edge 34 and second edge 35 are the two edges on the −Z-direction side of the four edges of first magnetic body 3A that extends in the Y-direction, and element-facing surface 36 is the −Z-direction side of the two surfaces of first magnetic body 3A that are directed in the Z-direction. First fixed magnetization portion 32 is provided along first edge 34 in the Y-direction, and second fixed magnetization portion 33 is provided along second edge 35 in the Y-direction. First fixed magnetization portion 32 is provided along the entire length of first edge 34 but may be provided along only a part of first edge 34. Second fixed magnetization portion 33 is provided along the entire length of second edge 35 but may be provided along only a part of second edge 35. In a plan view from the Y-direction that is orthogonal to each of the X- and Z-directions, first fixed magnetization portion 32 is closer to first magnetic field sensing element 2A than is center 3A1 of first magnetic body 3A. Similarly, in a plan view from the Y-direction that is orthogonal to each of the X- and Z-directions, second fixed magnetization portion 33 is closer to second magnetic field sensing element 2B than is center 3B1 of first magnetic body 3B.

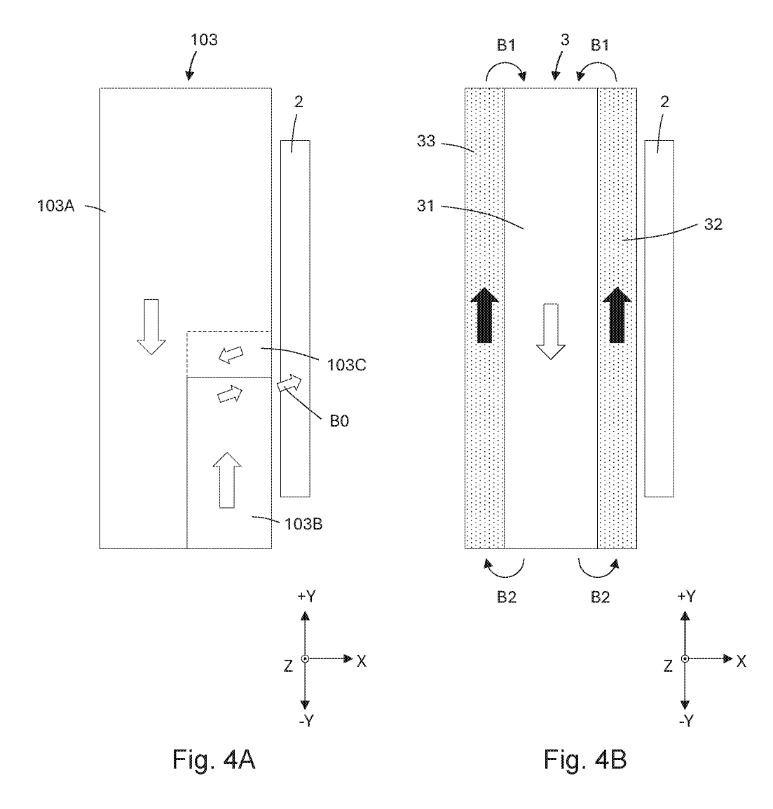

FIG. 4A shows a plan view of magnetic body 103 of a comparative example that lacks first fixed magnetization portion 32 and second fixed magnetization portion 33. The white arrows in the figure represent the directions of magnetization or leakage fields. Magnetic body 103 in this comparative example is made entirely of a soft magnetic material. When, for example, a large magnetic field that exceeds the coercive force is applied to magnetic body 103, the magnetic body may not return to its original magnetization state after the application of the magnetic field stops. FIG. 4A shows an example of the magnetization of magnetic body 103 when a large magnetic field is applied in the −Y-direction, following which the application of the magnetic field is stopped. Magnetic body 103 is magnetized as a whole in the −Y-direction but is partially magnetized in the +Y-direction. If magnetic body 103 consists only of portion 103A that is magnetized in the −Y-direction and portion 103B that is magnetized in the +Y-direction, the leakage field leaking from magnetic body 103 is limited. However, since the magnetization state of magnetic body 103 is autonomously determined such that the magnetostatic energy is minimized, irregularly magnetized portion 103C may appear. In this portion 103C, magnetic domains magnetized in directions other than the +Y-direction and −Y-direction are likely to occur. Leakage magnetic field B0 is likely to be generated from portion 103C.

Leakage magnetic field B0 that occurs in this way is applied to magnetic field sensing element 2 even when no external magnetic field is applied. As a result, the output of the magnetic sensor may be offset with respect to the output when no external magnetic field is applied. The magnetization state of magnetic body 103 is determined autonomously when the application of an external magnetic field is stopped, and the magnetization state is therefore difficult to control. Moreover, because this magnetization state is unstable and prone to change, the amount of offset may also change over time. Further, portion 103C that is magnetized in directions other than the +Y- and −Y-directions may also change the magnetic permeability to an external magnetic field in the X-direction, which is the measurement target. These factors may change the intensity of the magnetic field applied through magnetic body 103 to magnetic field sensing element 2 even when a magnetic field of the same intensity is applied to the magnetic sensor, and as a result, may change the sensitivity of the magnetic sensor.

FIG. 4B shows a plan view of first magnetic body 3A (hereinafter referred to simply as magnetic body 3) of the present embodiment provided with first fixed magnetization portion 32 and second fixed magnetization portion 33. The white and black arrows in the figure represent the directions of magnetization. First fixed magnetization portion 32 and second fixed magnetization portion 33 are magnetized in the +Y-direction (they may also be magnetized in the −Y-direction). Since first fixed magnetization portion 32 and second fixed magnetization portion 33 have a higher coercive force than soft magnetic layer 31, the magnetization state is less likely to fluctuate even when a large magnetic field is applied. In other words, even when a large magnetic field is applied and then stopped, first fixed magnetization portion 32 and second fixed magnetization portion 33 are likely to remain magnetized in the +Y-direction.

Soft magnetic layer 31 is magnetized autonomously such that the magnetostatic energy is minimized, but the direction of magnetization is usually in roughly the −Y-direction. This magnetization state results due to realization of a magnetic flux return structure (the flow of magnetic flux that exits first fixed magnetization portion 32 and second fixed magnetization portion 33, is then absorbed in soft magnetic layer 31 between first fixed magnetization portion 32 and second fixed magnetization portion 33 as shown by arrows B1, and then finally is absorbed in first fixed magnetization portion 32 and second fixed magnetization portion 33 as shown by arrows B2). As a result, the magnetostatic energy is minimized, whereby leakage magnetic field B0 is suppressed to enable reduction of the offset. The formation of magnetic domains whose magnetization directions are tilted from the Y-direction is suppressed, thereby enabling suppression of fluctuations in sensitivity. The magnetization state of soft magnetic layer 31 is determined autonomously and is consequently not necessarily magnetized in the −Y-direction. Magnetic domains oriented in directions tilted from the Y-direction may therefore still occur, but since soft magnetic layer 31 is farther from first magnetic field sensing element 2A than first fixed magnetization portion 32 and farther from second magnetic field sensing element 2B than second fixed magnetization portion 33, the effect of such magnetic domains on first and second magnetic field sensing elements 2A and 2B is small.

Referring to FIG. 2A, the sum 32X + 33X of the dimension 32X of first fixed magnetization portion 32 in the X-direction and dimension 33X of second fixed magnetization portion 33 in the X-direction can be made less than 2/3 of dimension 3X of magnetic body 3 in the X-direction. These dimensions facilitate the formation of a flux return structure because the total area of first and second fixed magnetization portions 32 and 33 on the element-facing surface 36 is roughly the same as the area of soft magnetic layer 31. As shown in FIG. 2B, dimension 32X in the X-direction of first fixed magnetization portion 32 can be made larger than dimension 32Z in the Z-direction, and dimension 33X of second fixed magnetization portion 33 in the X-direction can be made larger than dimension 33Z in the Z-direction. The positional relationship between first and second fixed magnetization portions 32 and 33 and magnetic field sensing element 2 may be effective in suppressing the leakage magnetic field that is generated from side surfaces 39 of first and second fixed magnetization portions 32 and 33. In such a case, although not shown in the drawings, dimension 32Z in the Z-direction of first fixed magnetization portion 32 can be made larger than dimension 32X in the X-direction, and dimension 33Z in the Z-direction of second fixed magnetization portion 33 can be made larger than dimension 33X in the X-direction. In this case, first fixed magnetization portion 32 and second fixed magnetization portion 33 may be formed over the entire surface of side surface 39 (the entire dimension in the Z-direction).

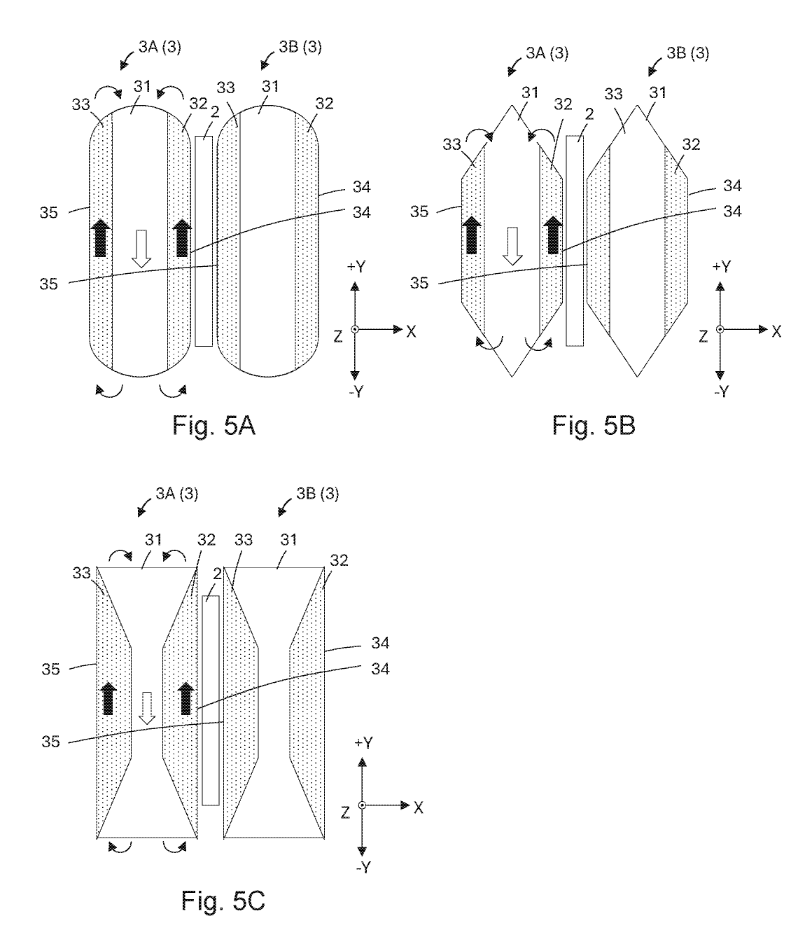

FIGS. 5A-5C show plan views of other configurations of magnetic body 3. Magnetic body 3 is not limited to a rectangular shape as viewed from the Z-direction and may have various shapes. For example, as shown in FIG. 5A, magnetic body 3 may be rounded at both ends in the Y-direction (the longitudinal direction). Alternatively, as shown in FIG. 5B, magnetic body 3 may be shaped with triangular ends in the Y-direction (the longitudinal direction). Alternatively, as shown in FIG. 5C, first fixed magnetization portion 32 and second fixed magnetization portion 33 may be trapezoidal in shape with edges 34 and 35 being the long sides and the sides opposite the long sides in the X-direction being the short sides.

### Modifications

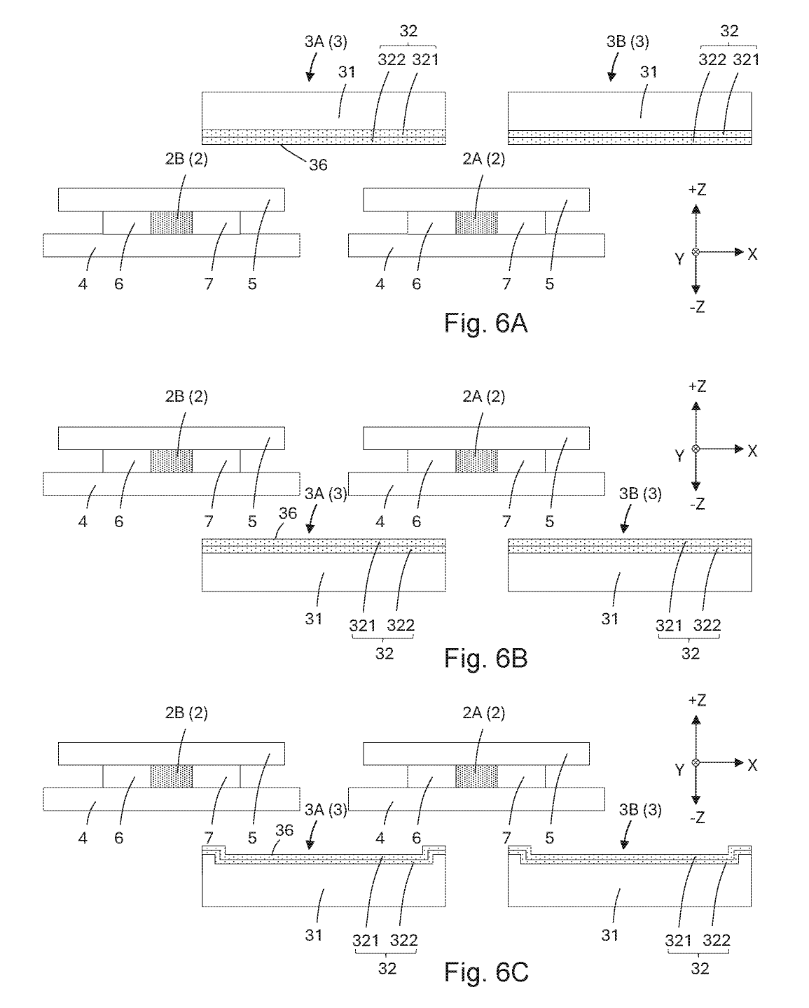

FIGS. 6A-6C are enlarged cross-sectional views of portions of magnetic sensor 1 according to modifications of the first embodiment. In FIG. 6A, the plurality of magnetic bodies 3 are provided on the upper side (the +Z-direction side) in the stacking direction of the plurality of magnetic field sensing elements 2, while in FIGS. 6B and 6C, the plurality of magnetic bodies 3 are provided on the lower side (the −Z-direction side) in the stacking direction of the plurality of magnetic field sensing elements 2. In either modification, first fixed magnetization portion 32 is provided over the entire area of element-facing surface 36, and this configuration enables simplification of the manufacturing process. The magnetization direction of first fixed magnetization portion 32 is fixed in the +Y- direction or −Y-direction, and soft magnetic layer 31 is magnetized autonomously so as to minimize the magnetostatic energy. In these modifications, the reflux structure of magnetic flux as in the first embodiment is unlikely to occur, but soft magnetic layer 31 is separated from magnetic field sensing element 2, and as a result, even if magnetic domains oriented in the X-direction occur, their effects are limited. As shown in FIG. 6C, a part of soft magnetic layer 31 may be removed by milling and first fixed magnetization portion 32 then formed on the milled portion.

### Second Embodiment

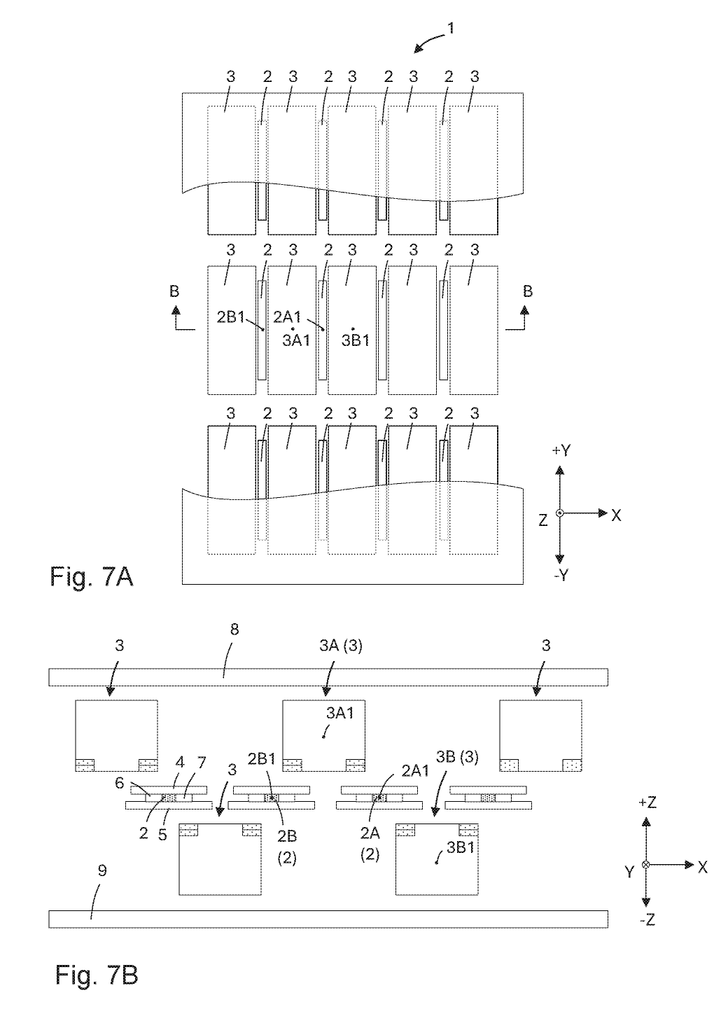

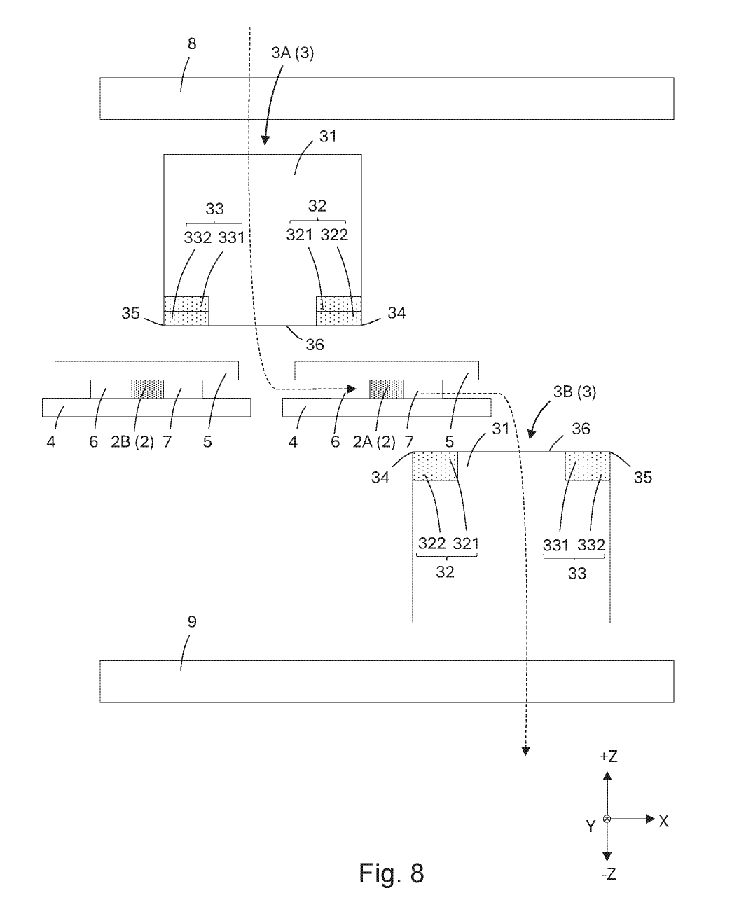

FIG. 7A is a plan view of magnetic sensor 1 according to the second embodiment. FIG. 7B is a cross-sectional view along line B−B in FIG. 7A of magnetic sensor 1 according to the second embodiment. FIG. 8 is an enlarged cross-sectional view of a portion of FIG. 7B. First electrode 4, second electrode 5, first soft magnetic layer 6, and second soft magnetic layer 7 are not shown in FIG. 7A. In the present embodiment, description will focus mainly on differences from the first embodiment. Configuration and effects that are the same as those of the first embodiment will be omitted from the explanation. The plurality of magnetic field sensing elements 2 detects magnetic fields in the X-direction. In the X-direction, center 2A1 of first magnetic field sensing element 2A is at a position between center 3A1 of first magnetic body 3A and center 3B1 of second magnetic body 3B. In the Z-direction, second magnetic body 3B is located on the opposite side of the plurality of magnetic field sensing elements 2 (that include first magnetic field sensing element 2A and second magnetic field sensing element 2B) from first magnetic body 3A. In other words, some of the plurality of magnetic bodies 3 are on one side (+Z-direction side) of the plurality of magnetic field sensing elements 2 in the Z-direction and the rest are on the other side (−Z-direction side) in the Z-direction.

Magnetic sensor 1 further comprises third soft magnetic layer 8 and fourth soft magnetic layer 9 that sandwich the plurality of magnetic bodies 3 and the plurality of magnetic field sensing elements 2 in the Z-direction. Third soft magnetic layer 8 and fourth soft magnetic layer 9 can be made of a soft magnetic material such as NiFe. The dimensions in the Z-direction of third soft magnetic layer 8 and fourth soft magnetic layer 9 are smaller than the dimensions in the X-direction and Y-direction, and third and fourth soft magnetic layers 8 and 9 therefore may absorb magnetic flux in the X-direction and Y-direction but allow magnetic flux in the Z-direction to pass through. Magnetic flux in the Z-direction is diverted in the X-direction by first magnetic body 3A and second magnetic body 3B as well as by first soft magnetic layer 6 and second soft magnetic layer 7 and is detected by magnetic field sensing element 2. In this way, magnetic sensor 1 of the present embodiment detects magnetic fields in the Z-direction. Although not shown, the entirely of magnetic sensor 1 shown in FIG. 7A may be rotated by 90 degrees such that the plurality of magnetic field sensing elements 2 detects magnetic fields in the Y-direction. First soft magnetic layer 6 and second soft magnetic layer 7 are not essential and one or both one of these layers may be omitted.

The configuration of first magnetic body 3A is similar to that of first magnetic body 3A of the first embodiment. First magnetic body 3A includes first edge 34 along the Y-direction that faces first magnetic field sensing element 2A, second edge 35 along the Y-direction that faces second magnetic field sensing element 2B, and element-facing surface 36 that extends between first edge 34 and second edge 35 and that faces at least one of first magnetic field sensing element 2A and second magnetic field sensing element 2B. First fixed magnetization portion 32 is provided along first edge 34 in the Y-direction and second fixed magnetization portion 33 is provided along second edge 35 in the Y-direction. In a plan view from the Y-direction that is orthogonal to each of the X-direction and Z-direction, first fixed magnetization portion 32 is closer to first magnetic field sensing element 2A than is center 3A1 of first magnetic body 3A. The configuration of second magnetic body 3B is similar to that of first magnetic body 3A, but first edge 34, second edge 35, and element-facing surface 36 are provided on the +Z-direction side, i.e., on side closer to first magnetic field sensing element 2A.

### Modification

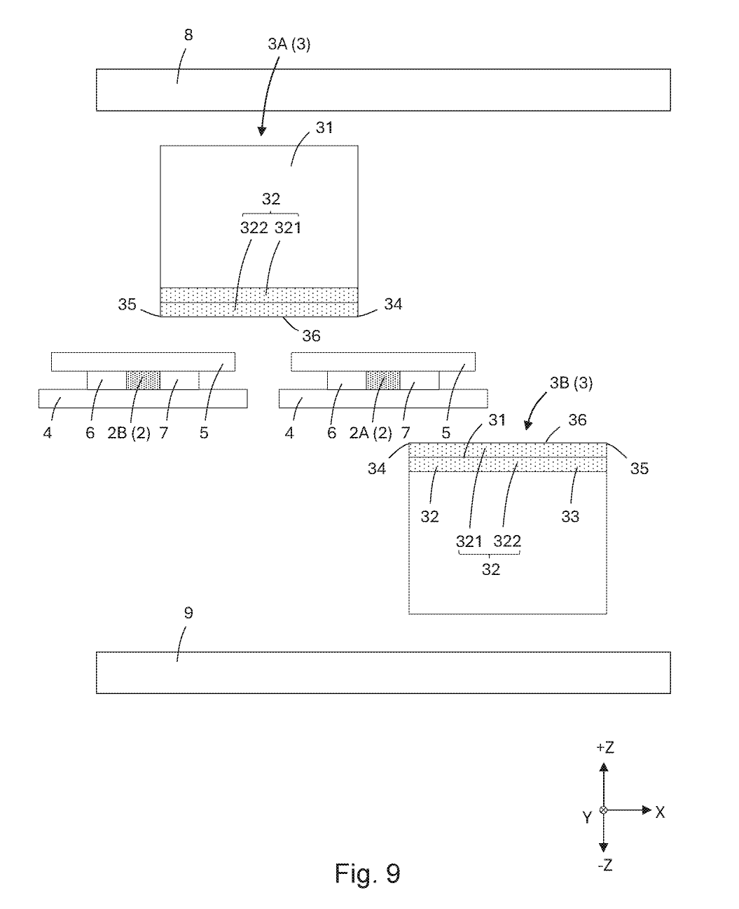

FIG. 9 shows an enlarged cross-sectional view of a portion of magnetic sensor 1 according to a modification of the second embodiment. Each of first fixed magnetization portions 32 of first magnetic body 3A and second magnetic body 3B is provided across the entire surface of each corresponding element-facing surface 36. The present modification has the same effect as the modification of the first embodiment; i.e., the omission of second fixed magnetization portion 33 simplifies the manufacturing process.

### Another Modification

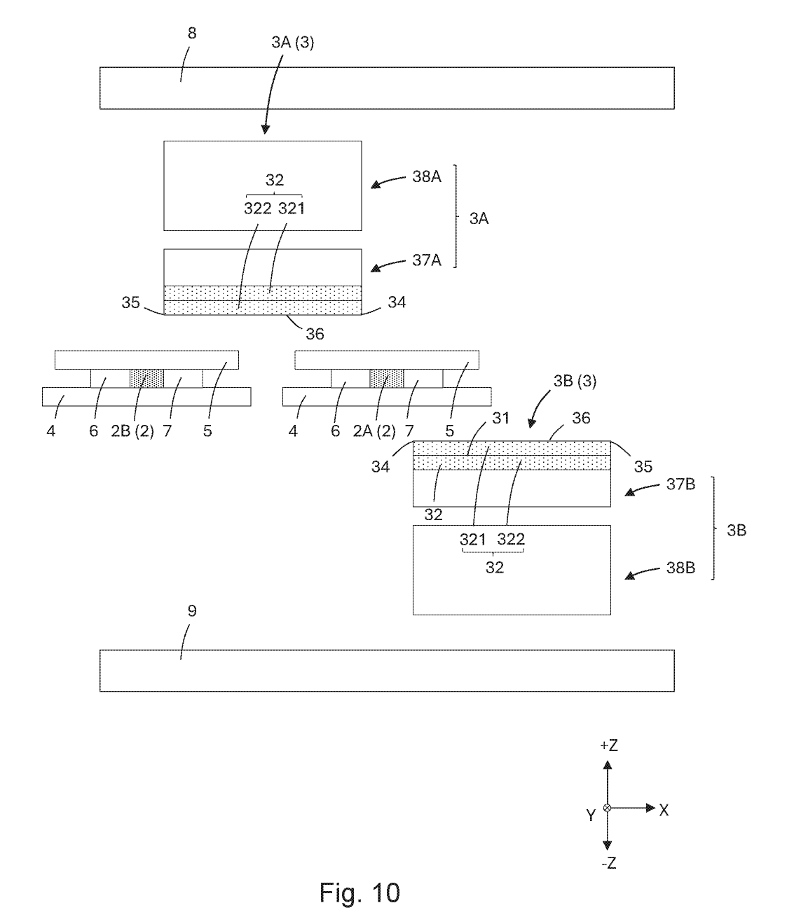

FIG. 10 shows an enlarged cross-sectional view of a portion of magnetic sensor 1 according to another modification of the second embodiment. First magnetic body 3A is divided into two parts (first part 37A and second part 38A) and second magnetic body 3B is divided into two parts (first part 37B and second part 38B) in the Z-direction. First fixed magnetization portion 32 may be provided on first parts 37A and 37B, while second parts 38A and 38B may be formed only of a soft magnetic material. In general, a magnetic sensor that detects a magnetic field in the Z-direction tends to have a greater thickness (the Z-direction dimension) of the magnetic body than a magnetic sensor that detects magnetic fields in the X-direction or Y-direction. Therefore, as shown in FIG. 9, the ratio of the thickness of first fixed magnetization portion 32 to soft magnetic layer 31 becomes smaller than in the first embodiment, and the magnetization state of soft magnetic layer 31 may easily become irregular. Since first fixed magnetization portion 32 is provided on first parts 37A and 37B, soft magnetic layer 31 of first parts 37A and 37B is more likely to be magnetized relatively regularly. Second parts 38A and 38B tend to be irregularly magnetized, but the effect is small because these parts are separated from magnetic field sensing element 2. In the present modification, first fixed magnetization portion 32 is provided over the entire surface of element-facing surface 36, but first fixed magnetization portion 32 and second fixed magnetization portion 33 may also be provided as shown in FIG. 8.

According to the present disclosure, a magnetic sensor can be provided that can suppress leakage magnetic fields generated from a magnetic body after application of an external magnetic field.

### LIST OF REFERENCE NUMERALS

1 magnetic sensor

2A first magnetic field sensing element

2B second magnetic field sensing element

3A first magnetic body

3B second magnetic body

31 soft magnetic layer

32 first fixed magnetization portion

33 second fixed magnetization portion

34 first edge

35 second edge

36 element-facing surface

321 first fixed magnetization film

322 base film

X first direction

Y third direction

Z second direction

1. A magnetic sensor comprising:
a first magnetic field sensing element that has a magnetic field sensing direction in a first direction; and
a magnetic body, wherein
in the first direction, the center of the magnetic body is at a position different from the center of the first magnetic field sensing element,
the magnetic body is located apart from the first magnetic field sensing element in a second direction which is a thickness direction of the first magnetic field sensing element,
the magnetic body includes a soft magnetic layer and a first fixed magnetization portion whose magnetization direction is fixed with respect to an external magnetic field, and
the first fixed magnetization portion is closer to the first magnetic field sensing element than is the center of the magnetic body in a plan view from a third direction that is orthogonal to each of the first direction and the second direction.

2. The magnetic sensor according to claim 1, wherein the length of the magnetic body in the third direction is longer than the length of the magnetic body in the first direction, and the first fixed magnetization portion is provided along an edge along the third direction.

3. A magnetic sensor comprising:
a first magnetic field sensing element that has a magnetic field sensing direction in a first direction; and
a magnetic body, wherein
in the first direction, the center of the magnetic body is at a position different from the center of the first magnetic field sensing element,
the magnetic body is located apart from the first magnetic field sensing element in a second direction which is a thickness direction of the first magnetic field sensing element,
the magnetic body includes a soft magnetic layer and a first fixed magnetization portion whose magnetization direction is fixed with respect to an external magnetic field, and
the magnetic body includes an edge that faces the first magnetic field sensing element along a third direction that is orthogonal to each of the first direction and the second direction, and the first fixed magnetization portion is provided along the edge.

4. The magnetic sensor according to claim 3, wherein the length of the magnetic body in the third direction is longer than the length of the magnetic body in the first direction.

5. The magnetic sensor according to claim 1, wherein the first fixed magnetization portion includes an antiferromagnetic material.

6. The magnetic sensor according to claim 1, wherein the first fixed magnetization portion includes a hard magnetic material.

7. The magnetic sensor according to claim 1, further comprising a second magnetic field sensing element that has a magnetic field sensing direction in the first direction, wherein
in the first direction, the center of the magnetic body is at a position between the center of the first magnetic field sensing element and the center of the second magnetic field sensing element, and in the second direction, the second magnetic field sensing element is on the same side of the magnetic body as the first magnetic field sensing element.

8. The magnetic sensor according to claim 7, wherein the magnetic body includes a second fixed magnetization portion that has a fixed magnetization direction with respect to an external magnetic field, and
in a plan view from the third direction, the second fixed magnetization portion is located apart from the first fixed magnetization portion and is closer to the second magnetic field sensing element than is the center of the magnetic body.

9. The magnetic sensor according to claim 8, wherein
the dimension of the first fixed magnetization portion in the first direction is larger than the dimension of the first fixed magnetization portion in the second direction, and
the dimension of the second fixed magnetization portion in the first direction is larger than the dimension of the second fixed magnetization portion in the second direction.

10. The magnetic sensor according to claim 8, wherein
the dimension of the first fixed magnetization portion in the second direction is larger than the dimension of the first fixed magnetization portion in the first direction, and
the dimension of the second fixed magnetization portion in the second direction is larger than the dimension of the second fixed magnetization portion in the first direction.

11. The magnetic sensor according to claim 8, wherein the sum of the dimensions of the first fixed magnetization portion and the second fixed magnetization portion in the first direction is less than 2/3 of the dimension of the magnetic body in the first direction.

12. The magnetic sensor according to claim 7, wherein the magnetic body has an element-facing surface that faces at least one of the first magnetic field sensing element and the second magnetic field sensing element, and the first fixed magnetization portion is provided over the entire area of the element-facing surface.

13. The magnetic sensor according to claim 1, further comprising another magnetic body that is located apart from the magnetic body in the first direction, wherein
the center of the first magnetic field sensing element is at a position between the center of the magnetic body and the center of the other magnetic body in the first direction, and
the other magnetic body is in the same position as the magnetic body in the second direction.

14. The magnetic sensor according to claim 1, further comprising another magnetic body that is located apart from the magnetic body in the first direction, wherein
the center of the first magnetic field sensing element is at a position between the center of the magnetic body and the center of the other magnetic body in the first direction, and
the other magnetic body is provided on the opposite side of the first magnetic field sensing element from the magnetic body in the second direction.

15. The magnetic sensor according to claim 14, wherein the magnetic body and the other magnetic body are each divided into a plurality of parts in the second direction.
